(19) United States
(12) Patent Application Publication
(10) Pub. No.: US 2009/0166062 A1
(43) Pub. Date: Jul. 2, 2009

(54) PRINTED CIRCUIT BOARD ASSEMBLY

(75) Inventors: ZHI-PING WU, Shenzhen City (CN); JENG-DA WU, Tu-Cheng (TW); YU-HSU LIN, San Jose, CA (US); CHIH-HANG CHAO, Tu-Cheng (TW); LIANG-LIANG CAO, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen (CN); HON HAI PRECISION INDUSTRY CO., LTD., Tu-Cheng (TW)

(21) Appl. No.: 12/118,684

(22) Filed: May 10, 2008

(30) Foreign Application Priority Data
Dec. 29, 2007 (CN) 200720201814.7

(51) Int. Cl. H05K 1/00

(52) U.S. Cl. 174/252

(57) ABSTRACT

A printed circuit board assembly includes a printed circuit board, a carrier, a semiconductor chip mounted on the carrier, a plurality of tin balls soldered between the printed circuit board and the carrier for transmitting signals, and a heat sink glued to the semiconductor chip to dissipate heat. A pressing portion is formed on the bottom of the heat sink and does not make contact with the semiconductor chip. The pressing portion contacts with the periphery of the carrier to reinforce the tin balls located between the printed circuit board and the carrier.

### BACKGROUND

1. Technical Field

The present invention relates to printed circuit board assemblies, particularly to a printed circuit board assembly with tin balls located between a semiconductor chip carrier and a printed circuit board.

2. Description of Related Art

A semiconductor chip carrier is usually mounted on a printed circuit board by jointing solder spots of the semiconductor chip carrier to the printed circuit board via tin balls. Conventional tin balls include lead. Because of good capability of lead for resisting shock, the tin balls are not easily damaged. However, due to the dangers of lead polluting the environment and posing a danger to people, nonleaded tin balls are now commonly used in the process of mounting a semiconductor chip carrier to a printed circuit board. However, because of poor capability of non-leaded tin balls to resist shock, they are easily damaged when the printed circuit board suffers an impact, thereby affecting signal transmission between the semiconductor chip carrier and the board.

What is needed, therefore, is a printed circuit board assembly which minimizes or prevents damage to tin balls between a semiconductor chip carrier and a printed circuit board when the printed circuit board suffers an impact.

### SUMMARY

A printed circuit board assembly includes a printed circuit board, a carrier, a semiconductor chip mounted on the carrier, a plurality of tin balls soldered between the printed circuit board and the carrier for transmitting signals, and a heat sink glued to the semiconductor chip to dissipate heat. A pressing portion is formed on the bottom of the heat sink and does not make contact with the semiconductor chip. The pressing portion contacts with the periphery of the carrier to reinforce the tin balls located between the printed circuit board and the carrier.

Other advantages and novel features will be drawn from the following detailed description of preferred embodiments with attached drawings, in which:

### BRIEF DESCRIPTION OF THE DRAWINGS

FIG. 1 is an assembled, isometric view of a printed circuit board assembly in accordance with an exemplary embodiment of the present invention;

FIG. 2 is an exploded, front view of the circuit board assembly of FIG. 1;

FIG. 3 is an isometric view of a heat sink of FIG. 1;

FIG. 4 is an assembled, front view of the printed circuit board assembly of FIG. 2;

FIG. 5 is an isometric view of a heat sink according to a prior art; and

FIG. 6 is an assembled, front view of a printed circuit board assembly according to the prior art.

### DETAILED DESCRIPTION OF THE INVENTION

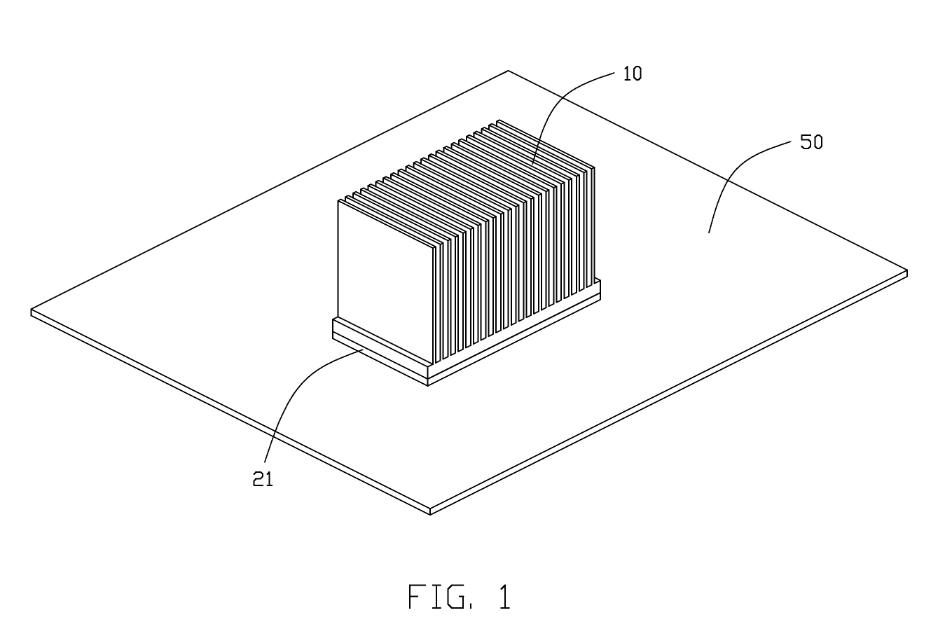

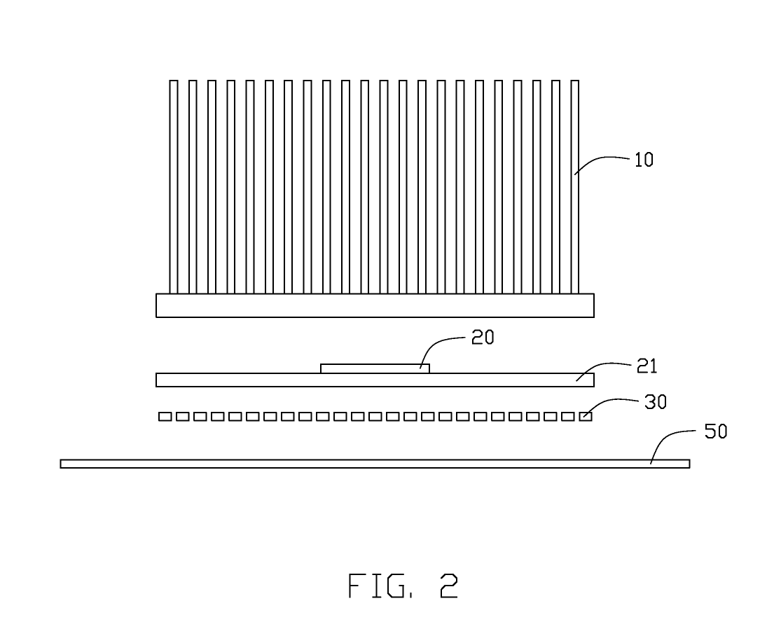

Referring to FIG. 1 and FIG. 2, a printed circuit board assembly in accordance with the present invention includes a heat sink 10, a semiconductor chip 20, a carrier 21 configured for carrying the semiconductor chip 20, and a plurality of tin balls 30 located between the carrier 21 and a printed circuit board (PCB) 50. The tin balls 30 are arrayed in a rectangular area. Each tin ball 30 can act as a conduit for transmission of signals between the carrier 21 and the printed circuit board 50. A bottom surface area of the heat sink 10, an area of the carrier 21 and a distribution area of the tin balls 30 are equal.

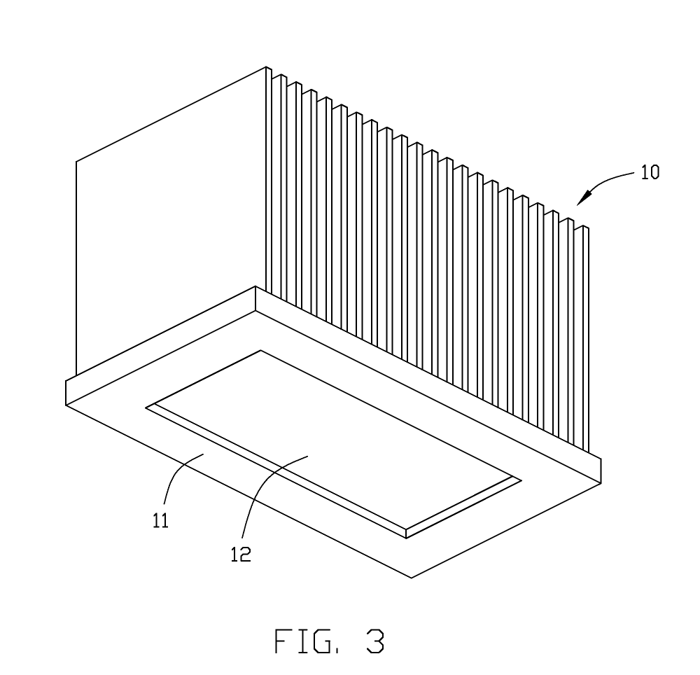

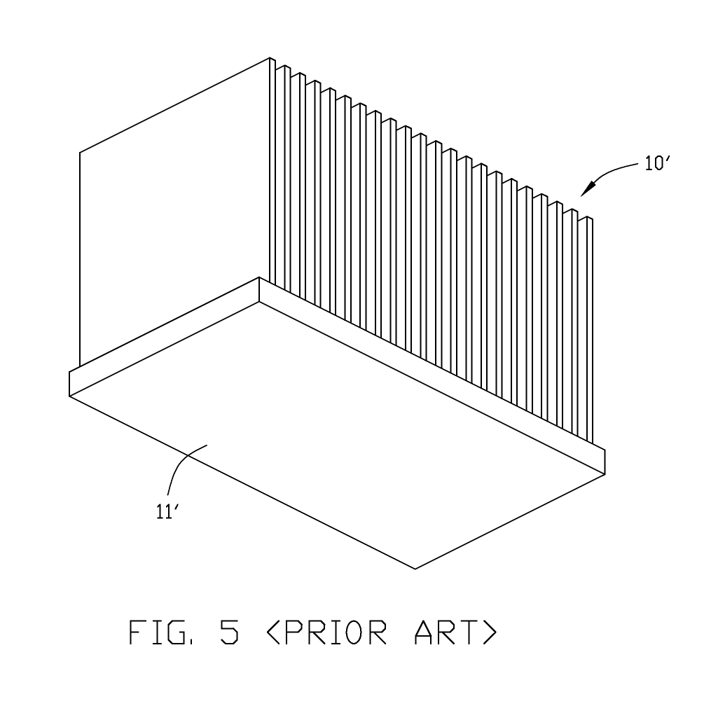

Referring also to FIG. 3, a pressing portion 11 is formed on the bottom of the heat sink 10 along the periphery thereof. The pressing portion 11 is a part of the heat sink 10. The pressing portion 11 is made of heat conducting materials, such as Cu and/or Al. A groove 12 is defined in the middle portion of the bottom of the heat sink 10, and is encircled by the pressing portion 11. An area of the groove 12 is smaller than the bottom surface area of the heat sink 10. The semiconductor chip 20 is can be adhered to the inside of the groove 12. A height of the pressing portion 11 is equal to a thickness of the semiconductor chip 20. The pressing portion 11 contacts the carrier 21. As shown in FIG. 5 according to a prior art, the heat sink 10′ has no a groove. The pressing portion 11′ is formed on the whole bottom of the heat sink 10′.

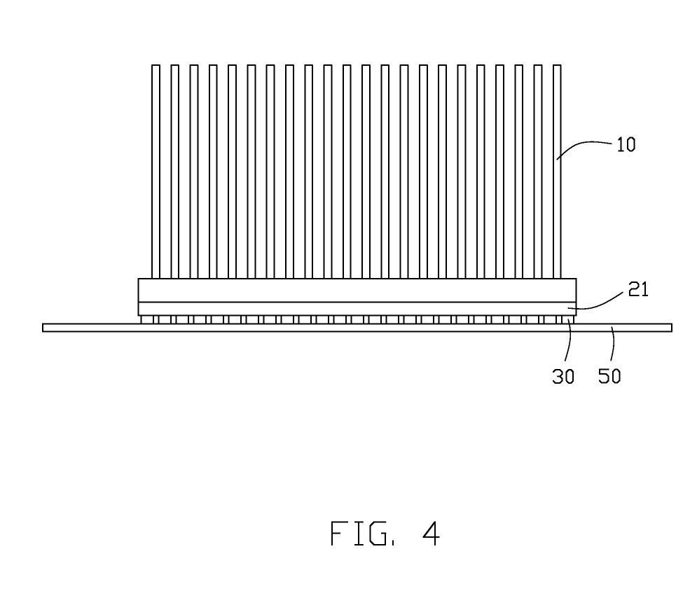

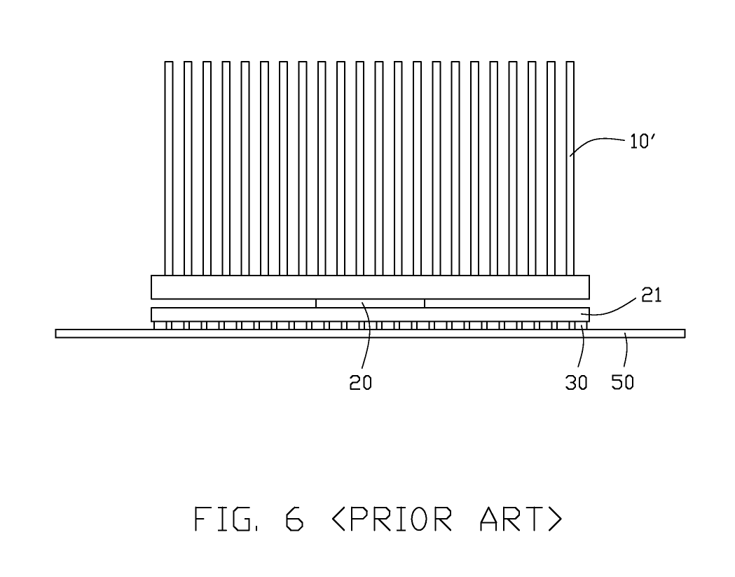

Referring also to FIG. 4, in assembly, the tin balls 30 are soldered between the carrier 21 and the printed circuit board 50 to transmit signals. Then, the semiconductor chip 20 is adhered to the inside of the groove 12 of the heat sink 10 with, for example, glue. The pressing portion 11 of the heat sink 10 firmly presses on the carrier 21 to firmly sandwich the tin balls 30 between the carrier 21 and the printed circuit board 50. As shown in FIG. 6 according to the prior art, the pressing portion 11′ does not contact with the carrier 21 due to the semiconductor chip 20 on the carrier 21.

A software LS-DYNA is used for simulating stress distribution on the tin balls 30 when the printed circuit board 50 suffers an impact. The simulated conditions are set as follows: the initial velocity of the printed circuit board 50 is 3.22 meters/second when the printed circuit board 50 suffers an impact. The maximum acceleration is determined to be 30 times the acceleration of gravity when the printed circuit board 50 is struck. The simulation according to the above conditions shows that the greatest stress on the tin balls 30 is 10.44 Mpa when the pressing portion 11 contacts with the carrier 21, and 14.61 MPa, when the pressing portion 11′ does not contact with the carrier 21. Therefore, when the printed circuit board 50 of FIG. 1 suffers an impact, chances of which the tin balls 30 suffer damage are minimized or possibly eliminated. The pressing portion 11 reinforces the tin balls 30 that are located under the carrier 21, and thus protects these tin balls 30 from damage.

Furthermore, the pressing portion 11 of the heat sink 10, which is made of heat conductive materials, can effectively reduce the temperature of the carrier 21 and the semiconductor chip 20. A software is used for simulating the effectiveness of the heat sink 10. The temperature of the semiconductor chip 20 is 78.6980° C. without the pressing portion 11, and 76.8920° C. with the pressing portion 11. So the pressing portion 11 of the heat sink 10 also aids in heat dissipation.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board assembly, comprising:
a printed circuit board;
a carrier;
a semiconductor chip mounted on the carrier;
a plurality of tin balls located between the printed circuit board and the carrier for transmitting signals;
a heat sink adhered to the semiconductor chip to dissipate heat, a pressing portion on the bottom of the heat sink and being free of contact with the semiconductor chip, the pressing portion being in contact with the carrier; and
an area comprising of the location in which the tin balls are positioned, wherein the pressing portion is in contact with the carrier along the periphery of the area.

2. The printed circuit board assembly as described in claim 1, wherein a groove is defined in the middle portion of the pressing portion.

3. The printed circuit board assembly as described in claim 2, wherein the pressing portion is located along the periphery to surround the periphery of the bottom of the heat sink.

4. The printed circuit board assembly as described in claim 1, wherein the undersurface area of the heat sink, the carrier area and said area are equal and are aligned.

5. The printed circuit board assembly as described in claim 1, wherein a height of the pressing portion is equal to a thickness of the semiconductor chip.

6. A printed circuit board assembly, comprising:
a heat sink defining a groove thereunder;
a semiconductor chip secured to a printed circuit board and within the groove of the heat sink;
a carrier configured for holding the semiconductor chip thereon; and
a plurality of tin balls provided located between the carrier and the printed circuit board, wherein the tin balls are capable of transmitting signals;
wherein a bottom portion of the heat sink contacts with the carrier due and the semiconductor chip resides within the groove, thereby the heat sink is in contact with the carrier corresponding to the tin balls located beneath the edges of the carrier.

7. The printed circuit board assembly as described in claim 6, wherein an undersurface area of the heat sink, an area of the carrier and a distribution area of the tin balls are equal and aligned.

8. The printed circuit board assembly as described in claim 6, wherein a depth of the groove is equal to a thickness of the semiconductor chip.
